(19) United States
(12) Patent Application Publication
(10) Pub. No.: US 2022/0147320 A1
(43) Pub. Date: May 12, 2022

(54) HIGHLY PARALLEL PROCESSING SYSTEM

(71) Applicant: Vizzio Technologies Pte Ltd, Singapore (SG)

(72) Inventor: Seng Fook LEE, Singapore (SG)

(21) Appl. No.: 17/521,874

(22) Filed: Nov. 9, 2021

Related U.S. Application Data
(60) Provisional application No. 63/111,094, filed on Nov. 9, 2020.
(60) Provisional application No. 63/111,095, filed on Nov. 9, 2020.
(60) Provisional application No. 63/111,097, filed on Nov. 9, 2020.
(60) Provisional application No. 63/111,098, filed on Nov. 9, 2020.
(60) Provisional application No. 63/111,096, filed on Nov. 9, 2020.
(60) Provisional application No. 63/111,102, filed on Nov. 9, 2020.
(60) Provisional application No. 63/111,101, filed on Nov. 9, 2020.

(51) Int. Cl. G06F 8/30; G06F 9/48; G06F 30/12

(52) U.S. Cl. CPC G06F 8/314; G06F 30/12; G06F 9/4881

(57) ABSTRACT

Disclosed is a highly parallel processing system for processing graphics applications written in a high-level programming language. The high-performance computing architecture includes a graphics processing unit with numerous processing cores, such as hundreds to thousands of processing cores. The graphics processing unit includes routines written in a low-level programming language. The routines of the graphics processing unit are invoked to process highly computational intensive tasks by the numerous processing cores in parallel.

### CROSS-REFERENCE

The present disclosure claims the benefit of US Provisional Applications with serial numbers 63/111,094, 63/111,095, 63/111,097, 63/111,098, 63/111,096, 63/111,102, and 63/111,101, which are all filed on Nov. 09, 2020. All disclosures are herein incorporated by reference in their entireties for all purposes.

### FIELD

The present disclosure relates to a highly parallel processing system and method. In particular, the present disclosure relates to a highly parallel processing system and method to perform heavy computational intensive graphics and modeling processes in real-time.

### BACKGROUND

Computer vision has become an important part of today's society. For example, computer vision supports crucial applications in medical, manufacturing, military intelligence, surveillance as well as other domains. Computer vision tasks can be divided into fundamental steps, such as image acquisition, pre-processing, feature extraction, detection or segmentation and high-level processing. Various computer vision tasks, such as classification, objection detection, 3D computer graphics and modeling tasks, require computationally intensive algorithms or processes.

However, the processing of heavy intensive computational computer vision tasks by conventional processing systems is ineffective. For example, it is difficult for conventional processing systems to perform classification, objection detection, 3D computer graphics and modeling processes in real-time. This hinders the performance or effectiveness of computer vision applications.

From the foregoing discussion, it is desirable to provide a high-performance processing system for computer vision or graphics applications.

### SUMMARY

Embodiments of the present disclosure generally relate to high parallel processing systems and methods. In particular, embodiments relate to highly parallel processing systems and methods to perform heavy computational intensive graphics and modeling processes in real-time.

In one embodiment, a highly parallel processing system is disclosed. The processing system includes a central processing unit which is configured to run an application. The processing system includes a highly parallel processing unit which includes an array of at least hundreds of parallel processing cores and libraries of graphics codes written in a low-level programming language. The central processing unit calls the highly parallel processing unit to execute highly computational intensive tasks of the application in parallel.

In another embodiment, a method for highly parallel processing of a software application is disclosed. The method includes running the software application by a central processing unit. The central processing unit calls a highly parallel processing unit having an array of at least hundreds of parallel processing cores and libraries of graphics codes written in a low-level programming language for executing the highly intensive computational tasks of the software application in parallel by the numerous processing cores using the graphics codes. The highly parallel processing unit returns the results of the highly intensive computational tasks to the central processing unit.

These and other objects, along with advantages and features of the present embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present disclosure are described with reference to the following drawings, in which:

FIG. 1 shows a simplified diagram of an embodiment of a high-speed processing system; and

FIG. 2 shows an exemplary pseudo-code residing in a graphics processing unit (GPU).

### DETAILED DESCRIPTION

Embodiments described herein generally relate to highly parallel processing systems. For example, embodiments relate to high-speed processing architectures. Highly parallel processing systems are particularly useful for processing computer vision and 3D graphics applications which include graphics, including 3D graphics.

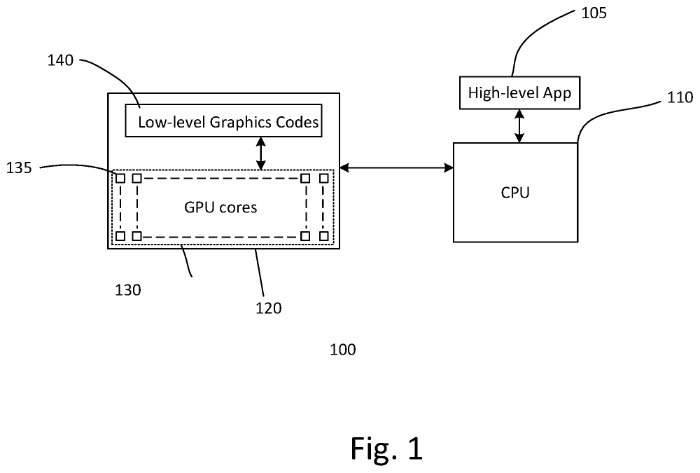

FIG. 1 shows a block diagram of an embodiment of a highly parallel processing system 100. The highly parallel processing system includes a central processing unit (CPU) 110. The CPU, for example, runs a software application written in a high-level programming language (high-level App). The high-level application may be written in various high-level programming languages, such as C++, Java, JS, Python, as well as other high-level programming languages. The high-level App, for example, may be a 3D graphics or computer vision application. The high-level App may include a user interface (UI) as well as other functions. For example, the high-level App may issue calls to the application programming interfaces (APIs). Other types of applications may also be useful.

In one embodiment, the highly parallel processing system includes a highly parallel processing unit (HPPU) 120. The HPPU, in one embodiment, is a graphics processing unit (GPU). Other types of HPPUs may also be useful. The HPPU, for example, may be an application specific integrated circuit (ASIC) or field programmable gate array (FPGA) based processing unit. HPPUs may also include, for example, Tensor Processing Units (TPUs), Neural Processing Units (NPUs) as well as other types of massively parallel processing units in the form of software and chipsets.

In one embodiment, the GPU includes an array 130 of hundreds to thousands of processing cores 135, such as Compute Unified Device Architecture (CUDA) cores 135. Graphics codes or routines 140 are provided within the framework of the GPU. For example, the GPU framework includes libraries of graphics codes. The graphics codes are employed for various heavy intensive computational computer vision tasks, including classification, objection detection, 3D computer graphics and modeling tasks. In one embodiment, the graphics codes are written in a low-level programming language. For example, the low-level graphics routines are written using native APIs, such as Vulkan. Other low-level programming languages may also be employed, depending on, for example, the type of HPPU. The codes are processed across thousands of parallel cores.

The CPU, when it encounters heavy computational tasks while running the high-level App, invokes the GPU. For example, the CPU makes calls to the GPU, invoking the codes for parallel processing of the tasks across the thousands of cores. When the tasks are completed, the GPU returns the results to the CPU.

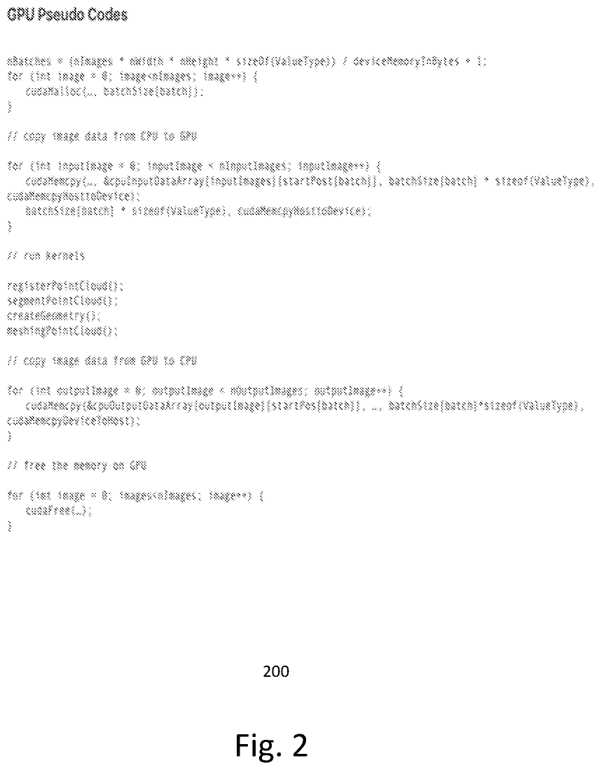

FIG. 2 shows exemplary pseudo-codes 200 residing in the HPPU. For example, the codes are written in a low-level programming language, such as Vulkan in the case of a GPU.

As described, the HPPU enables massively parallel applications to be created. For example, utilizing high-performance codes written in a low-level programming language, the tasks are accelerated by thousands of parallel threads running on cores. As such, execution of computation—and bandwidth-hungry graphics applications is accelerated with the present highly parallel processing system. The highly parallel processing system with the libraries and frameworks of codes underpin the ongoing revolution in artificial intelligence known as Deep Learning.

The inventive concept of the present disclosure may be embodied in other specific forms without departing from the spirit or essential characteristics thereof. The foregoing embodiments, therefore, are to be considered in all respects illustrative rather than limiting the invention described herein.

1. A highly parallel processing system comprising:
a central processing unit (CPU), the CPU is configured to run an application;
a highly parallel processing unit (HPPU) comprising
an array of at least hundreds of parallel processing cores,
libraries of graphics codes written in a low-level programming language; and
wherein the CPU calls the HPPU for execution of highly computational intensive tasks of the application in parallel.

2. The highly parallel processing system of claim 1 wherein the HPPU comprises a graphics processing unit (GPU).

3. The highly parallel processing system of claim 2 wherein the array of processing cores comprises Compute Unified Device Architecture (CUDA) cores.

4. The highly parallel process system of claim 2 the low-level programming language of the graphics codes comprises Vulkan.

5. The highly parallel processing system of claim 1 wherein the array of processing cores comprises thousands of processing cores.

6. The highly parallel processing system of claim 1 wherein the execution of the highly computational intensive tasks are accelerated by thousands of parallel threads running on processing cores of the HPPU.

7. The highly parallel processing system of claim 1 wherein the graphics codes are for performing heavy intensive computational computer vision tasks.

8. The highly parallel processing system of claim 7 wherein the heavy intensive computational computer vision tasks includes classification, objection detection, 3D computer graphics and modeling tasks.

9. The highly parallel processing system of claim 4 wherein the graphics codes are for performing heavy intensive computational computer vision tasks.

10. The highly parallel processing system of claim 9 wherein the heavy intensive computational computer vision tasks includes classification, objection detection, 3D computer graphics and modeling tasks.

11. A method for highly parallel processing of a software application comprising;
running the software application by a CPU;
calling a HPPU comprising an array of at least hundreds of parallel processing cores and libraries of graphics codes written in a low-level programming language for executing the highly intensive computational tasks of the software application in parallel by the numerous processing cores using the graphics codes; and
returning results of the highly intensive computational tasks to the CPU.

12. The method of claim 11 wherein the HPPU comprises a graphics processing unit (GPU).

13. The method of claim 12 wherein the array of processing cores comprises Compute Unified Device Architecture (CUDA) cores.

14. The method of claim 12 wherein the low-level programming language of the graphics codes comprises Vulkan.

15. The method of claim 13 wherein the array of processing cores comprises thousands of CUDA processing cores.

16. The method of claim 11 wherein executing the highly computational intensive tasks are accelerated by thousands of parallel threads running on the processing cores of the HPPU.

17. The method of claim 11 wherein the graphics codes are for performing heavy intensive computational computer vision tasks.

18. The method of claim 17 wherein the heavy intensive computational computer vision tasks includes classification, objection detection, 3D computer graphics and modeling tasks.

19. The method of claim 14 wherein the graphics codes are for performing heavy intensive computational computer vision tasks.

20. The method of claim 19 wherein the heavy intensive computational computer vision tasks includes classification, objection detection, 3D computer graphics and modeling tasks.
